(19) United States
(12) Patent Application Publication
(10) Pub. No.: US 2011/0005567 A1
(43) Pub. Date: Jan. 13, 2011

(54) MODULAR SOLAR PANEL SYSTEM

(75) Inventors: Donald VanderSluis, Sarasota, FL (US); Donald Sipes, Colorado Springs, CO (US)

Correspondence Address: HOLLAND & HART, LLP, P.O BOX 8749, DENVER, CO, 80201, US

(73) Assignee: Sunovia Energy Technologies Inc., Sarasota, FL (US)

(21) Appl. No.: 12/594,933

(22) PCT Filed: Apr. 7, 2008
(86) PCT No.: PCT/US08/04532

§ 371 Date: Sep. 27, 2010

Related U.S. Application Data
(60) Provisional application No. 60/910,560, filed on Apr. 6, 2007.

(51) Int. Cl. H01L 31/042

(52) U.S. Cl. 136/244

(57) ABSTRACT

Solar panels with an integrated DC-to-AC converter are provided. Such solar panels are usable as an independent generator of AC power or as part of an array of panels, and may be grid-connected with low initial cost of entry. Other aspects provide a panel with a built-in array of “micro-batteries” for energy storage in off-grid applications or grid-connected. Also provided herein, in another aspect, is an AC solar panel whose internal design and structure is optimized for the generation of AC power. Intrinsically, this includes an embedded DC-to-AC converter or converters. The AC solar panel may be used as an independent generator of AC power or as part of an array of panels. In still further aspects, one or more panels may be used as a remote AC power source with after sun-down power generation capability, low initial cost of entry and ease of deployment.

### CROSS-REFERENCE TO RELATED APPLICATIONS

The present application claims priority from U.S. Provisional Patent Application No. 60/910,560, filed on Apr. 6, 2007, the entire disclosure of which is incorporated herein by reference.

### FIELD

The present invention is directed to solar power systems and, more particularly, to modular solar power modules that may be used to form a solar power system.

### BACKGROUND

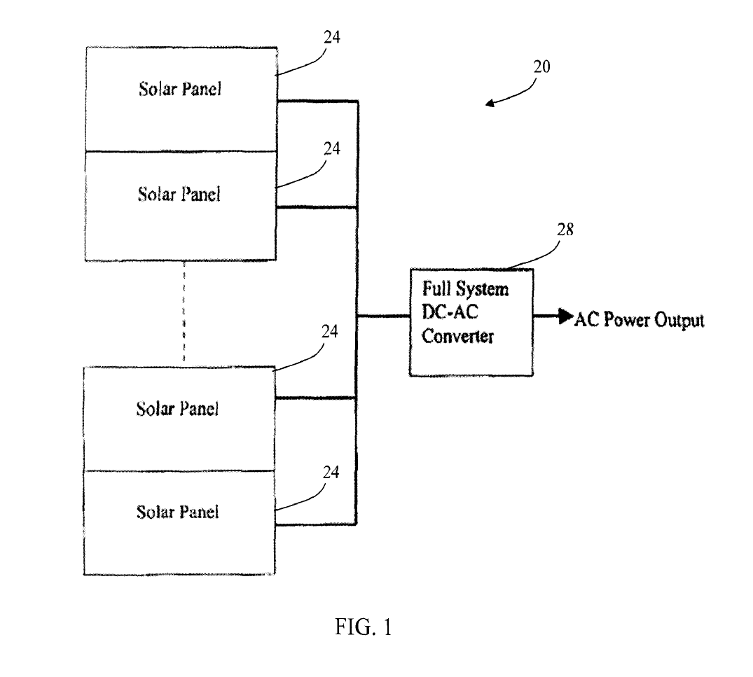

Solar power systems are an attractive form of producing energy from renewable resources. Such systems have recently gained popularity in part because these systems do not require burning of coal or petroleum products to generate electricity, thereby reducing pollution and greenhouse gasses associated with, for example, a traditional coal-fired power generation facility. As such, many individuals and businesses are desirous of having at least a portion of their power needs generated by such systems. FIG. 1 is a block diagram illustration of a typical solar power generation system 20. Such a system 20 may be installed, for example, on a residential or commercial building rooftop and be used to generate at least a portion of the electricity required for the building. The system 20 includes a number of solar panels 24. Such solar panels 24 are well known, and typically include a number of photo-voltaic cells that convert sunlight directly into direct current electricity. The solar panels 24 generally have the photo-voltaic cells arranged to provide a desired output DC voltage, typically 12 Volts or 24 Volts, at a nominal power output, such as 150 Watts. A number of solar panels 24 are arranged and connected to a DC-AC converter 28, also referred to as an inverter, that converts the DC power generated by the solar panels into AC power that may be used to power any of various electrical devices. The AC power from the inverter 28 is commonly tied into a power grid operated by a power utility, referred to as “grid-connected” systems. In some cases, the output of the solar system 20 is connected to a power storage system, typically an array of batteries, that store power from the system 20 for use when power demands exceed the power generated by the solar system 20. Such storage systems are generally used in areas where a separate power utility is not present, referred to as “off-grid” applications. Furthermore, some systems that are grid-connected also include a power storage system that may provide backup power in the event of a blackout or brownout of the power grid.

In many grid-connected systems, the power generated from the solar system is used to offset the amount of power required from the power utility, thereby lowering the amount of electricity required from the utility. Some governmental entities, such as state or local governments, require that utilities provide “net metering” to customers with solar systems. Net metering uses a single electric meter for a particular customer of the utility. In instances where the amount of power generated from the solar system exceeds the amount of power required from the power grid, the meter will spin backward, recording that power was transferred into the utility power grid. In instances where the amount of power required for the building exceeds the amount of power generated from the solar system (such as nighttime hours), the meter will spin forward, recording power that is received from the power grid. The utility customer is then billed for the net amount of power actually provided from the utility. In this manner, the customer is able to directly offset the unit cost of electricity by the amount of electricity generated by the solar system. In the event that the customer provides more power to the utility than was consumed during a billing cycle, the utility may provide a credit to the customer to be applied against future billing, or in some cases pay the customer for the power generated.

Some other states do not require net metering, and utilities in such states may require that customers using solar systems have a two electric meters. One meter measures power generated from the solar system, and the other meter measures the total amount of power used by the customer. The customer is then provided with a credit for the power generated by the solar system against the total amount of power used. Generally, the credit given to the customer is the wholesale cost of the power generated, and the power used by the customer is billed at retail prices. In this manner, the utility is not required to pay the customer the equivalent of retail prices for power generated by the customer.

### SUMMARY

Provided herein, in one aspect, is a solar panel with an integrated DC-to-AC converter. Such a solar panel is usable as an independent generator of AC power or as part of an array of panels, and may be grid-connected with low initial cost of entry. Other aspects provide a panel with a built-in array of “micro-batteries” for energy storage in off-grid applications or grid-connected. Also provided herein, in another aspect, is an AC solar panel whose internal design and structure is optimized for the generation of AC power. Intrinsically, this includes an embedded DC-to-AC converter or converters. The AC solar panel may be used as an independent generator of AC power or as part of an array of panels. In still further aspects, one or more panels may be used as a remote AC power source with after sun-down power generation capability, low initial cost of entry and ease of deployment.

### DETAILED DESCRIPTION

The present disclosure recognizes that, while solar power generation systems are useful to generate power, the cost of such systems requires that a significant investment be made for design, purchase, and installation of such systems. This initial investment is then recouped over time through reduced utility bills that result from the reduced amount of power required from the utility. System payback times, or the break-even point for the cost of a system versus the cost of equivalent amount of energy replaced from utility, are often on the order of a decade due to the high initial cost. Furthermore, such systems typically cost significantly more than an individual residential or small commercial property owner can afford to pay in a lump sum, or even over relatively short period of time. Thus options for such customers are often (a) not installing such a system, of (b) financing the cost of the system. As the cost of financing (e.g. a second mortgage) can significantly increase the system payback time, such an option is often not desirable. Therefore, high initial costs of such systems are slowing the adoption of more widespread installation of solar power generation systems for residential and small commercial customers.

The single most expensive individual cost of a typical present-day solar installation is the cost of the photo-voltaic material itself. However, the cumulative cost of the remaining system components is often significantly greater. For example, the mounting system, inverter, power storage (if installed), and the cost of the design and installation often can cost as much as the photo-voltaic material itself. Furthermore, due to the high cost of design and installation, as well as the costs of the inverter and other fixed components, the installation of present day systems is generally is done only for systems that have a significant power generation capability. For example, in many common designs, a minimum of twelve (12) solar panels are required, based on the operating requirements of these various other components. These high material and installation costs makes choosing solar power very difficult or impossible for many individuals who desire the benefits of deriving energy from the sun but do not have the means for the initial investment required for present day systems. The present disclosure provides modular solar panels that may be used individually, or in combination with other panels, to form a solar power system. In such a manner, a consumer may purchase and install portions of a solar power system at different times, thus easing the cost of such a system by allowing the expenditures of the system to be extended over a period of time.

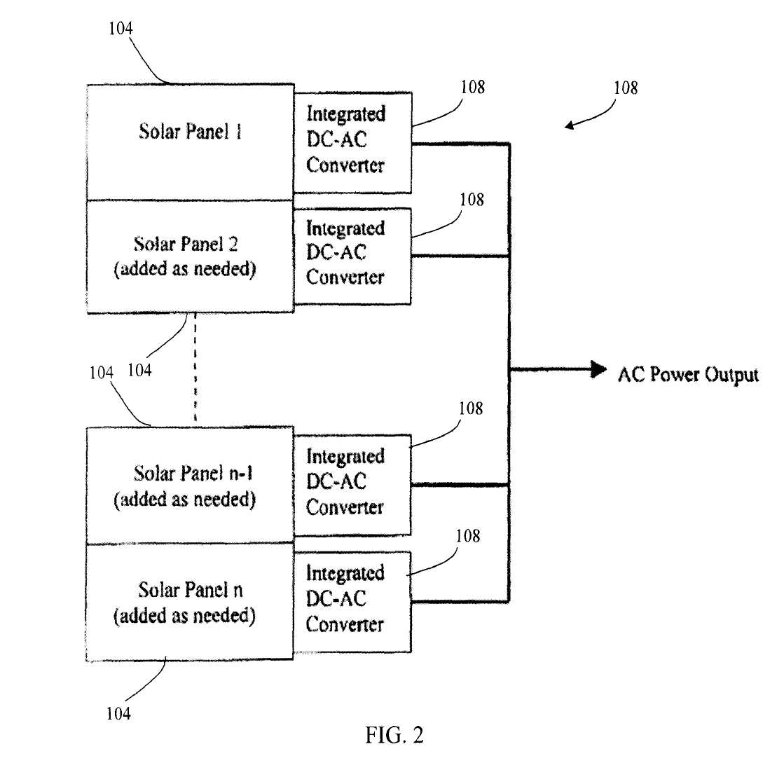

With reference now to FIG. 2, a system 100 of one embodiment is described. The system of FIG. 2 includes a number of solar panels 104, although a single solar panel 104 may be used. Each panel 104 may be manufactured of photo-voltaic cells, and/or other materials that are fabricated on a rigid or flexible substrate. In some embodiments, flexible photo-voltaic cells are used and provide reduced weight and relative ease for installation relative to embodiments comprising rigid cells. However, in other embodiments one or more of the solar panels are relatively large and rigid panels. In further embodiments, rigid cells are employed that include a semi-flexible, accordion-style structure may ease installation and therefore reduce costs. Although flexibility of some variety is present in solar panels of various embodiments to reduce weight and reduce costs of the support structure and installation, it will be understood that any type of solar panel may be used, with the exact type and material of the panel determined based on particular applications.

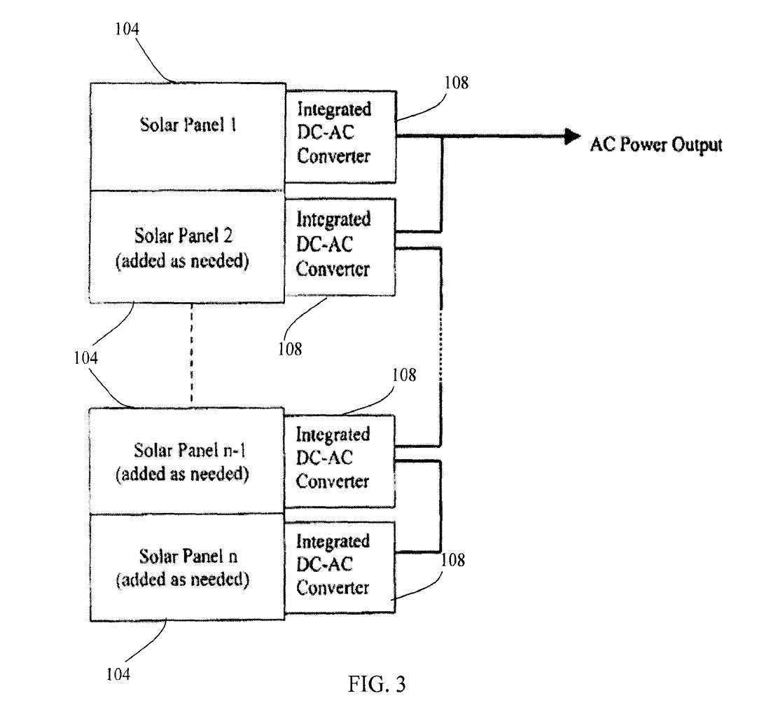

Each solar panel 104 includes in integrated DC-to-AC converter 108, also referred to interchangeably as an inverter. The DC-to-AC converter 108, as will be described in more detail below, may be interconnected with the AC power provided by a utility grid. A number of solar panels 104 with integrated DC-to-AC converters 108 may be interconnected with the utility grid in a parallel manner, as illustrated in FIG. 2. Alternatively, as illustrated in FIG. 3, the panels 104 may be “daisy-chained” together and interconnected to the utility grid. Such a configuration as illustrated in FIG. 3 may be useful in phase matching and output control as will be described in more detail below. In this manner, an initial solar panel 104 with embedded inverter 108 may be purchased and installed with a relatively small initial investment. Additional solar panels 104 may be purchased and installed to provide additional power generation as the particular customer has the funds to purchase and install such a system. For example, each solar panel 104 may generate 150 Watts of electricity. An individual residential customer may desire to install at least some solar power, but may not have the funds (either on hand, or available through financing) to install even a small a traditional solar power generation system. However, for example, in an embodiment a panel 104 produces 150 W of power, and has a significantly lower cost than even a small traditional system, and such a customer may have the funds to purchase and install such a single panel 104. As the customer obtains more funds over time, they may purchase additional panels 104 and expand the solar power generation system. Such a customer may, for example, purchase and install 12 such panels 104, one at a time, over the course of 10 years, ultimately having a 1.8 kW (12 panels that output 150 W each) system. While the total cost of such a system may be higher than the cost of a 1.8 kW system that is installed all at one time, the ability to purchase and install individual panels provides a system that may be purchased and installed by more residential and small commercial customers than could afford the large up-front costs of traditional solar power generation systems.

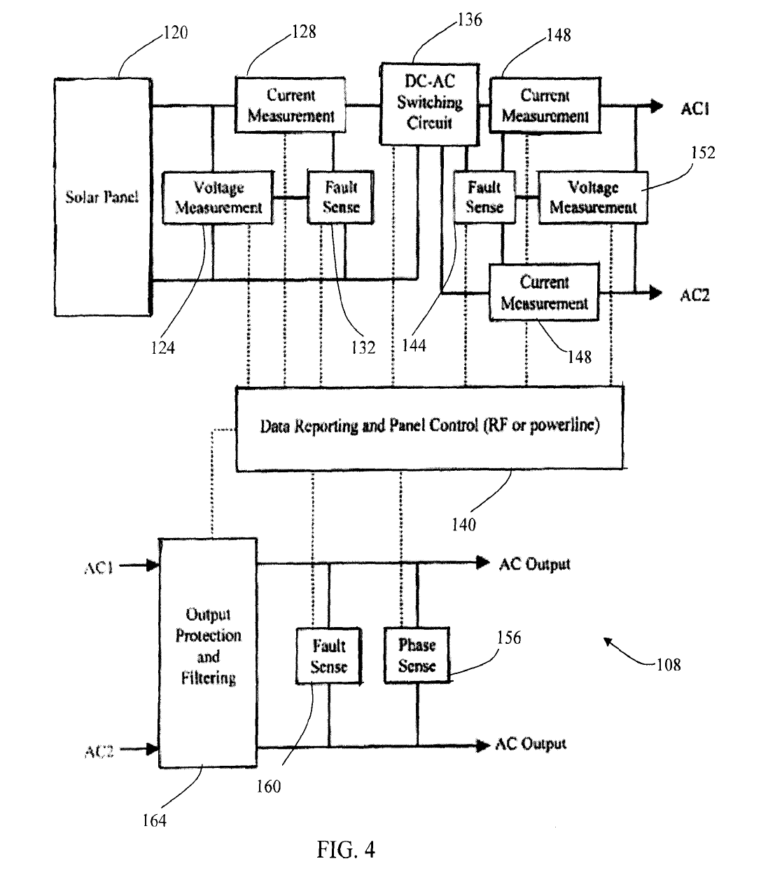

With reference now to FIG. 4, a block diagram illustration of a DC-to-AC converter 108 for an embodiment is now described. The inverter 108 of this embodiment performs functions of generally power conversion from DC to AC. On the DC (solar panel) side, a solar panel 120 provides DC output that is received at the inverter 108. The inverter 108 provides generated voltage sense through a voltage measurement circuit 124, a generated current sense through a current measurement circuit 128, and fault detection (such as a panel short) through a fault sense circuit 132. A DC-AC switching circuit 136 converts received DC power to AC, and current and voltage measurement circuits 124, 128 provide information to a panel control component 140 that may then adjust the DC-AC switching circuit 136 to achieve a desired AC output. A second fault sense 144 is interconnected to the DC-AC component and provides an indication of problems such as a panel short. On the AC output (load) side, the inverter provides an external current measurement circuits 148, an external voltage measurement circuit 152, an external AC phase sense circuit 156, a third fault sense circuit 160, as well as output protection and filtering 164. In the embodiment of FIG. 4, each DC-to-AC converter 108 includes a data reporting and panel control component 140 that, as discussed previously, controls the DC-AC switching circuit 136 and receives information regarding various measurements and senses from other components.

The data reporting and panel control component 140 also, in an embodiment, communicates panel data to one or more external components. For example, in one embodiment, the data reporting and panel control component 140 includes an RF transmitter that communicates panel information to an RF receiver that may be interconnected with a computer that collects and provides a display of the panel information. Such information may include power produced by the panel during a day, week, month, etc., the power currently being generated by the panel, and any faults that are sensed by the panel. The data reporting and panel control component 140 may also communicate with other panels in the solar power generation system, in order to provide a combined output of the panels that has desired characteristics. On one embodiment, the data reporting and panel control component 140 includes a Zigbee type RF transmitter, although it will be understood that any suitable RF communications device may be used, including, cellular, AM, FM, etc. In some embodiments, the data reporting and control panel 140 modulates information onto the power line itself, that may then be demodulated by one or more other components interconnected with the power line. In still further embodiment, the data reporting and panel control 140 also receives communications and may adjust one or more output settings of the panel based on the received communications.

The data reporting and panel control component 140, in other embodiments, can also perform functions related to coordinating the output of two or more panels. For example, should the utility grid go off-line (i.e., power failure), and two or more panels are present in the system, one inverter may act as “phase master” and all other panels may synchronize phase to the phase master inverter. Should the phase master inverter fall off-line, any other inverter may be capable of becoming phase master without external intervention. Furthermore, one or more solar panels may be shaded at a particular time. In an embodiment, an inverter driven by a solar panel in shade is operable to reduce its output accordingly down to, and including, zero current. Other panels not in shade continue to generate as before.

The output protection and filtering component 164 of FIG. 4 provides safety features to protect the solar panel module, and also to protect people and/or property that may come into contact with the panel from electrical dangers. For example, lightning or other power surges received by a panel are insulated from the remainder of the system. Individual panel modules may fail due to direct hit or surge, and in various embodiments, the components are designed such that the panel fails open rather than short. The inverter also may have ground fault interrupt (GFI) circuitry to protect users.

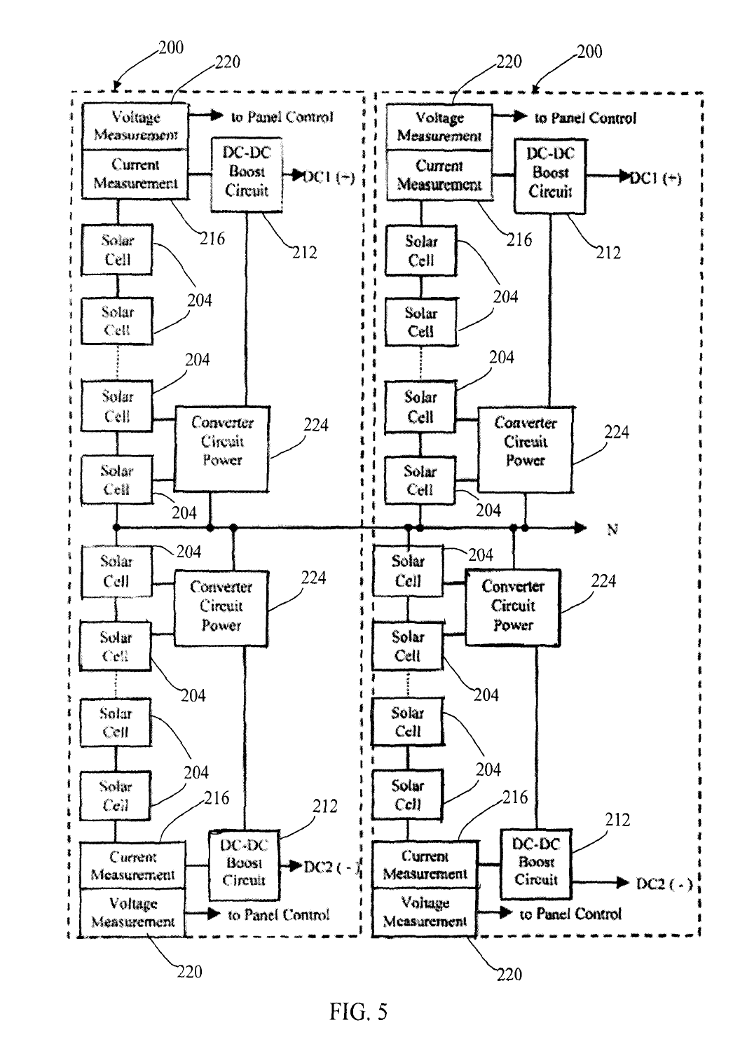

With reference now to FIG. 5, another embodiment is described. The solar panel 200 of this embodiment includes individual photo-voltaic cells 204, or sections of thin-film, that are arranged in a series string 208 to produce sufficient DC voltage that enhances efficiency of conversion to standard utility AC voltage. The embodiment of FIG. 5 includes a bipolar voltage (i.e. plus and minus voltage, relative to a neutral) output from each series string 208. Two or more strings 208 are then arranged in parallel to collectively provide current sufficient to generate the desired power output at the desired AC voltage. Also included are DC-DC boost converters 212 for each string 208 of cells 204 that provide increased DC voltage if necessary. In many typical operating conditions the series string 208 of solar cells 204 will produce sufficient voltage for efficient conversion to AC, in which case the boost converters may not be running, thereby increasing overall efficiency. In this manner, a single initial solar panel with embedded converter may be installed, or multiple panels may be installed, thereby providing an affordable solar power solution that is more convenient than other commonly available solutions to use, as well as being indefinitely expandable (daisy-chained or otherwise). Furthermore, the internal arrangement of solar cells 204 provides additional flexibility in that individual strings 208 of solar cells 204 that are not in shade can continue to produce power while other stings 208 may be in shade, thereby providing a panel that is highly adaptive to current lighting conditions. The solar panel 200, similarly as described above, include current measurement circuits 216, voltage measurement circuits 220, and converter circuit power components 224.

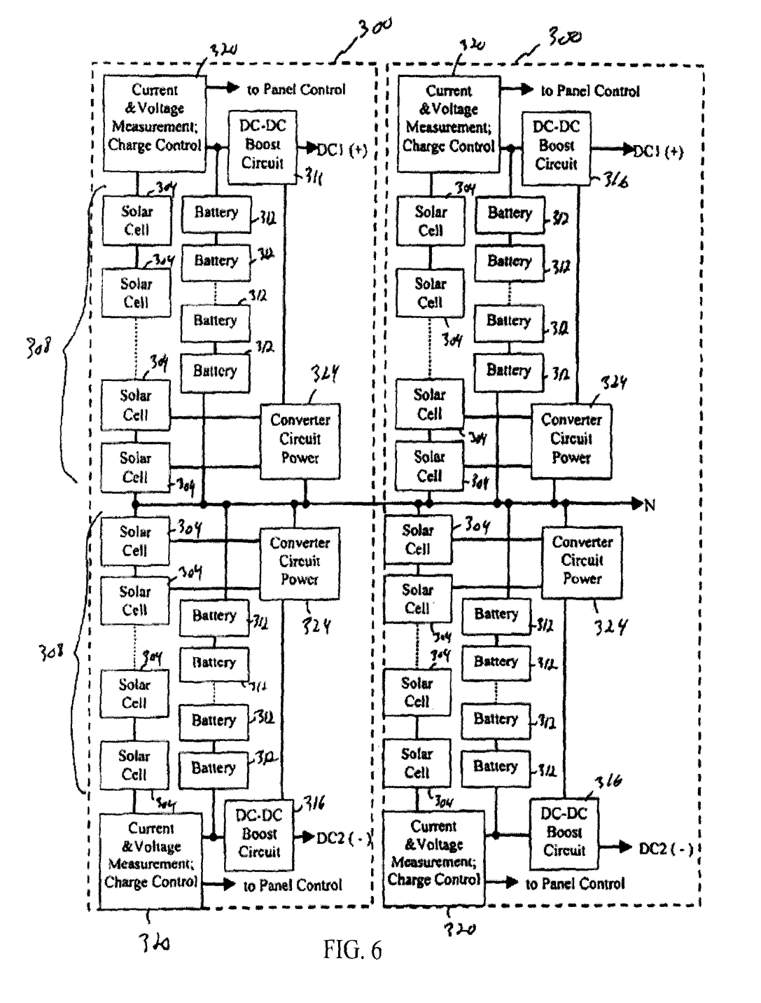

With reference now to FIG. 6, a solar panel 300, or portion thereof, for another embodiment is described. Similarly as described with respect to FIG. 5, the solar panel of the embodiment of FIG. 6 includes individual cells 304 or sections of thin-film, that are arranged in a series string 308 to produce sufficient DC voltage that enhances efficiency of conversion to standard utility AC voltage. The strings 308 of cells 304 are arranged to produce a bipolar voltage output from each series string 308, with two or more strings 308 arranged in parallel to collectively provide current sufficient to generate the desired power output at the desired AC voltage. In this embodiment, each string 308 includes two or more individual batteries 312 arranged in series to total a voltage appropriate to be charged by the series string 308 of solar cells 304. Also included are DC-DC boost converters 316 for each string 308 of cells 304 that provide increased DC voltage if necessary. In many typical operating conditions the series string 308 of solar cells 304 will produce sufficient voltage for efficient conversion to AC, in which case the boost converters 316 may not be running, thereby increasing overall efficiency. The solar panel 300, further includes current and voltage measurement and charge control circuits 320, and converter circuit power components 324.

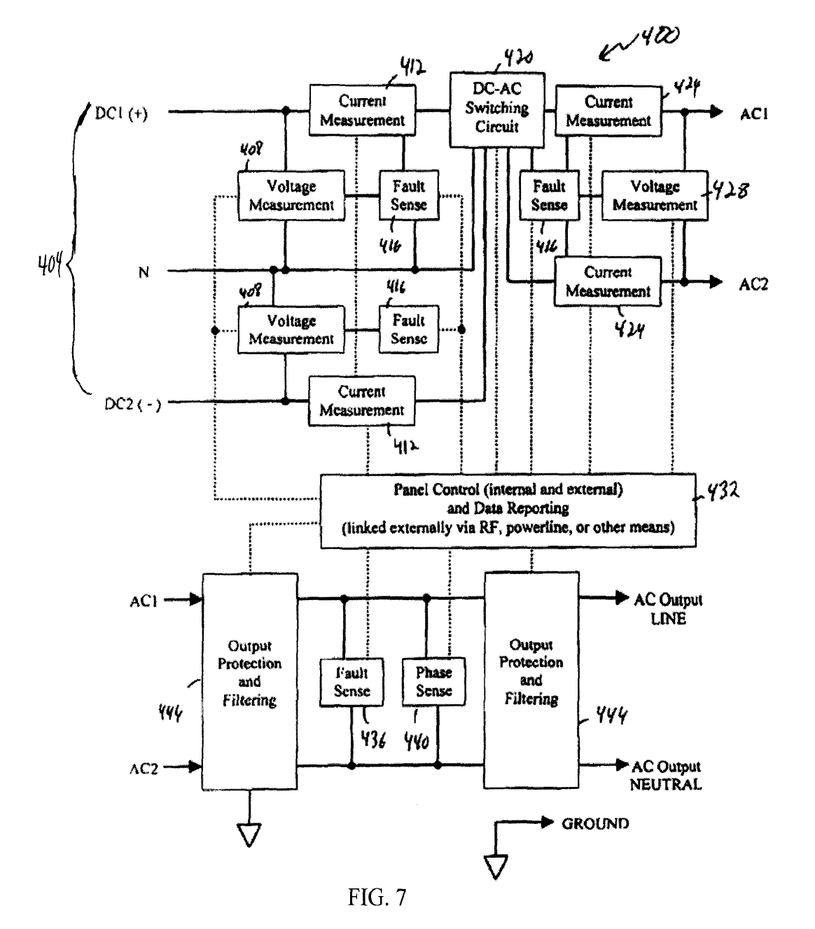

By providing batteries 312 integrated within the solar panel 300, each panel 300 may be used to provide power when current lighting conditions result in little or no power being produced from the solar cells 304 within the panel 300. Such a panel 300 may be used in off-grid applications, or in grid-connected applications where it is desired to have some amount of backup power in the event that power is unavailable from the grid, and the solar cells 304 within the panel 300 are not producing power. In such a manner, in conditions where the solar panel 300 is producing more power than is being consumed from the power converter, a panel controller may cause the charge control component 320 associated with each string 308 to charge the batteries 312. An exemplary power converter and panel controller will described in more detail below with reference to FIG. 7. In other embodiments, a panel controller may determine the current charge status of the batteries 312 for a particular string 308, and reduce the total power output of the panel 300 in order to charge batteries 312 that are below a desired level of charge. In such a manner, a panel 300 may recharge drained batteries 312 in addition to outputting power, or prior to outputting any power, as lighting conditions permit. Furthermore, a panel controller may perform battery management tasks to ensure that the batteries are not over/under charged, etc.

With reference now to FIG. 7, a block diagram illustration of a DC-to-AC converter 400 for an embodiment is now described. The DC-to-AC converter 400 of this embodiment includes a bipolar DC input 404, and may be used in conjunction with panels as illustrated in the embodiments of FIGS. 5 and 6. The DC-to-AC converter 400 of FIG. 7, generally performs functions related to power conversion from DC to AC. On the DC (solar panel) side, the converter comprises a generated voltage measurement 408 for each polarity, a generated current measurement 412 for each polarity, and fault sense 416 (e.g. panel short) for each polarity. A DC-AC switching circuit 420 converts the DC power to AC, and current and voltage measurement components 412, 408, respectively, provide information to a panel control component 432 that may then adjust the DC-AC switching circuit 420 to achieve a desired AC output. A fault sense 436 is interconnected to the DC-AC component and provides an indication of problems such as a panel short. On the AC output (load) side the DC-to-AC converter 400 includes an external AC phase sense 440, external voltage sense 428, external current sense 424, and output protection and filtering. In the embodiment of FIG. 7, each DC-to-AC converter 400 includes panel controller 432 (referred to as panel control and data reporting in FIG. 7) that performs functions including data reporting, control of the DC-AC switching circuit 420, control of the components within the inverter or the panel based on information regarding various measurements and senses from other components, and charge control if the panel includes any batteries.

The panel controller 432 also, in an embodiment, communicates panel data to one or more external components. For example, in one embodiment, the panel controller 432 includes an RF transmitter that communicates panel information to an RF receiver that may be interconnected with a computer that collects and provides a display of the panel information. Such information may include power produced by the panel during a day, week, month, etc., the power currently being generated by the panel, and/or any faults that are sensed by the panel. The panel controller 432 may also communicate with other panels in the solar power generation system, in order to provide a combined output of the panels that has desired characteristics. On one embodiment, the panel controller 432 includes a Zigbee type RF transmitter, although it will be understood that any suitable RF communications device may be used, including, cellular, AM, FM, etc. In some embodiments, the panel controller 432 modulates information onto the power line itself, that may then be demodulated by one or more other components interconnected with the power line. In still further embodiment, the panel controller 432 also receives communications and may adjust one or more output settings of the panel based on the received communications.

The panel controller 432, in other embodiments, can also perform functions related to coordinating the output of two or more panels. For example, should the utility grid go off-line (i.e., power failure), and two or more panels are present in the system, one inverter 400 may act as “phase master” and all other panels synchronize phase to the phase master inverter. Should the phase master inverter fall off-line, any other inverter may be capable of becoming phase master without external intervention. Furthermore, one or more solar panels may be shaded at a particular time. In an embodiment, an inverter driven by a solar panel in shade is operable to reduce its output accordingly down to, and including, zero current. Other panels not in shade continue to generate as before.

The output protection and filtering components 444 of FIG. 7 provide safety features to protect the solar panel, and also to protect people and/or property that may come into contact with the panel from electrical dangers. For example, lightning or other power surges received by a panel are insulated from the remainder of the system. Individual panels may fail due to direct hit or surge, and in various embodiments, the components are designed such that the panel fails open rather than short. The inverter also may have ground fault interrupt (GFI) circuitry to protect users.

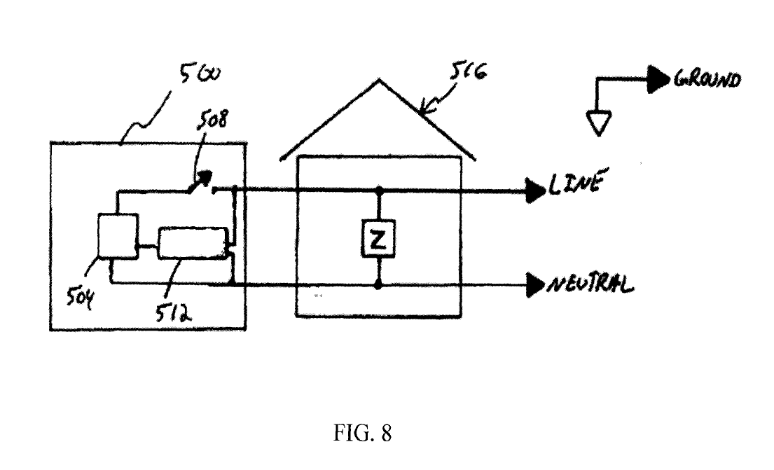

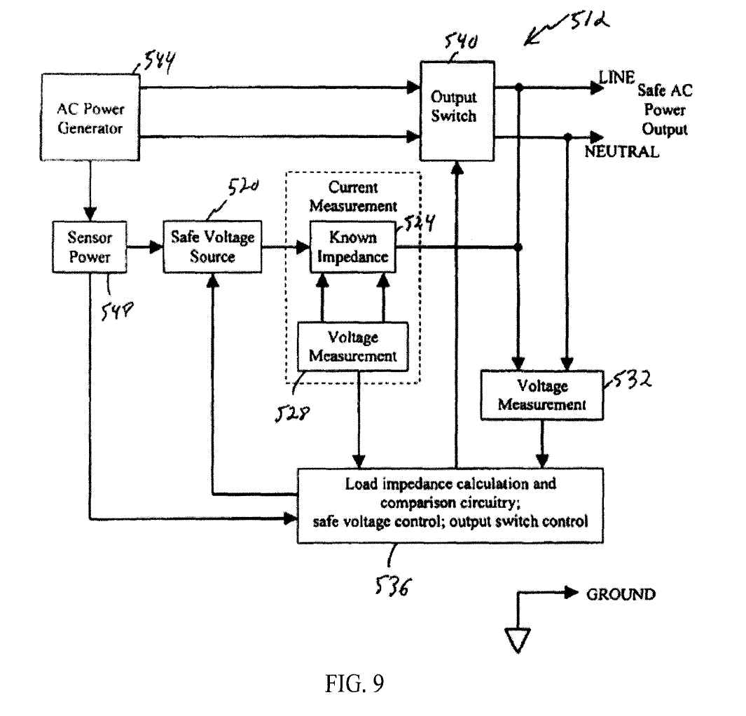

With reference now to FIGS. 8 and 9, another embodiment is described in which a panel determines that it is safe to apply power from the panel to a structure or other device and/or system that is interconnected with the panel. In this embodiment, the panel 500 includes a component that is capable of determining whether an interconnected load has an expected impedance. In this embodiment, if, for example, a short circuit across the output terminals of a panel 500 will be detected, and power will not be output from the panel 500 until it is determined that the short circuit has been corrected. Similarly, if a person is inadvertently contacting the output terminals, the panel 500 will detect an impedance that is not an expected impedance, and will not output power. In such a manner, a panel 500 discerns the difference between the panel output being interconnected with an expected load, and an unexpected or dangerous load, and supplies output power when an interconnected load impedance is within expected limits.

With reference now specifically to FIG. 8, an output impedance detection circuit of an embodiment is described. The detection circuit operates to determine the impedance that is seen from output terminals of a panel 500. An AC power generator 504 within the panel 500 is connected to an output through a switch 508, and an impedance detection circuit 512 measures the impedance at the output side of the switch 508. If a safe impedance level is detected, the power from the AC power generator 504 may be provided to the output through the switch 508. In the even that power is desired to be obtained from the panel 500, the impedance detection circuit 512 within the panel determines if utility power is present at the panel output. If utility power is present, this indicates that it is safe to provide power from the panel 500, because such is already present. If utility power is not present, the impedance Z at the panel output is measured and if this measured impedance is within predefined limits, power may be applied to the output through the switch 508. Typical structures 516, such as a residence, include common loads such as refrigerators, various other motor windings, transformer primaries, illumination sources and various other loads. Each of these loads presents impedance to the supply voltage that, in the absence of utility supplied voltage, can be measured as one collective load. With continued reference to FIG. 8, the collective impedance may be modeled as an impedance Z. A panel 500, or other power generation device, is illustrated as connected to the collective impedance Z through a panel output. If an unsafe condition is present, such as a short circuit across the output terminals, or a person or animal is in contact with the output terminals, the measured impedance will be significantly lower than the collective impedance Z. Thus, if the impedance detection component 512 tests the impedance present at the panel output terminals, a relatively low impedance is indicative of an unsafe condition. In such situations, the panel 500 determines that power from the panel 500 should not be applied to the output terminals of the panel. In the event that there is no external power present at the output terminals, and the measured impedance is within the predefined limits for safe application of power, the panel 500 may provide power to the output terminals.

With reference now to FIG. 9, impedance measurement circuitry for a panel of an embodiment is now described. In this embodiment, impedance is measured by the application of a safe test voltage from a safe test voltage source 520 through a known impedance 524 in series with the loads connected together in the structure. Voltage drop across known impedance 524 is measured at a first voltage measurement circuit 528, indicating current through the collective load. Voltage drop across the collective load is also measured at a second voltage measurement circuit 532. These two measurements provide sufficient information from which to calculate effective load impedance at a control circuit 536. The test voltage and duration of the period the test voltage is applied, and the frequency of the tests, are selected based upon the particular application in which the panel is to be used. If a pulse of sufficiently short duration is applied, capacitive impedance can be detected. Once load impedance is calculated, the value is compared to preset levels to determine whether power may be applied to the output of the panel. If a sage condition is detected, an output switch 540 may be switched to allow power from the AC power generator 544 to be provided to the panel output. The AC power generator 544 also provides power to a sensor power circuit 548 that is used to provide power to the safe voltage source 520 and the control circuit 536.

While the instant disclosure has been depicted, described, and is defined by reference to particular exemplary embodiments of the disclosure, such references do not imply a limitation on the disclosure, and no such limitation is to be inferred. The embodiments recited in this disclosure are capable of considerable modification, alteration, and equivalents in form and function, as will occur to those ordinarily skilled in the pertinent arts. The depicted and described embodiments are examples only, and are not exhaustive of the scope of the invention.

The foregoing disclosure sets forth various embodiments via the use of functional block diagrams and examples. It will be understood by those within the art that each block diagram component, operation and/or component described and/or illustrated herein may be implemented, individually and/or collectively, by a wide range of hardware, software, firmware, or any combination thereof. The foregoing disclosure also describes embodiments including components contained within other components (e.g., the various elements shown as components of solar panel). Such architectures are merely examples, and many other architectures can be implemented to achieve the same functionality.

What is claimed is:

1. A modular solar system, comprising:
at least two solar panels, each panel comprising:
a solar power generator;
a DC-to-AC converter; and
a control circuit that regulates output from the DC-to-AC converter,
wherein the at least two solar panels are interconnected to provide a combined power output that is regulated by the control circuit of each respective panel, and wherein at least an additional panel may be interconnected to the at least two solar panels after the at least two solar panels have been in operation.

2. The modular solar system, as claimed in claim 1, further comprising:
an impedance measurement circuit that is interconnected with an output of each panel; and
a control circuit interconnected to the impedance measurement circuit that provides power to the output of the panel when it is determined that the impedance measured by the impedance measurement circuit is within a predetermined range of impedance measurements.

3. The modular solar system, as claimed in claim 1, wherein at least one of the solar panels further comprises:
at least one battery that is charged by the solar power generator and provides power to the DC-to-AC converter when the solar power generator is not providing power.

4. The modular solar system, as claimed in claim 1, wherein the control circuit in at least one panel includes a communications portion and the power generated from the panel is provided according to information received at the communications portion.
